(19) United States
(12) Patent Application Publication
(10) Pub. No.: US 2025/0125163 A1
(43) Pub. Date: Apr. 17, 2025

(54) APPARATUS FOR DICING WAFER

(71) Applicant: Samsung Electronics Co., Ltd., Suwon-si (KR)

(72) Inventors: Kyo-Eun LEE, Suwon-si (KR); Young Chul KWON, Suwon-si (KR)

(73) Assignee: Samsung Electronics Co., Ltd., Suwon-si (KR)

(21) Appl. No.: 18/778,009

(22) Filed: Jul. 19, 2024

(30) Foreign Application Priority Data
Oct. 16, 2023 (KR) 10-2023-0137816

(51) Int. Cl. H01L 21/67; H01L 21/687

(52) U.S. Cl. CPC H01L 21/67092; H01L 21/67253; H01L 21/68764

(57) ABSTRACT

An apparatus for dicing a wafer includes a stage configured to receive a wafer, and move the wafer in a first direction, and a plurality of laser heads above the stage along the first direction, and as the stage moves the wafer in the first direction, the plurality of laser heads are configured to emit a plurality of laser beams onto the wafer along a plurality of cutting lines, the plurality of cutting lines extending in the first direction and each cutting line spaced apart from other cutting lines in a second direction, the second direction perpendicular to the first direction.

### CROSS-REFERENCE TO RELATED APPLICATION

This U.S. non-provisional application claims the benefit of priority under 35 U.S.C. 119 from Korean Patent Application No. 10-2023-0137816 filed on Oct. 16, 2023, in the Korean Intellectual Property Office, the contents of which in its entirety are herein incorporated by reference.

### BACKGROUND

Various example embodiments of the inventive concepts relate to an apparatus for dicing a wafer, a system including the apparatus, and/or a method of operating the apparatus.

A semiconductor device may be manufactured using a variety of processes. For example, a process of cutting a wafer, etc., may be included in the semiconductor manufacturing process. The wafer may be cut in a variety of ways. The wafer may be cut using, for example, a blade or a laser. To cut the wafer using a laser, a stealth dicing scheme that focuses a laser beam on an inside of the wafer may be used. The wafer may be cut by focusing the laser beam onto and/or into the interior of a wafer to form a crack and a modified area inside the wafer.

### SUMMARY

Various example embodiments of the inventive concepts provide for an apparatus for dicing a wafer with improved productivity, a system including the apparatus, and/or a method of operating the apparatus, etc.

However, the example embodiments of the inventive concepts are not limited to the above-mentioned purposes. Other purposes and advantages according to one or more of the example embodiments of the inventive concepts that are not mentioned may be understood based on following descriptions, and may be more clearly understood based on the disclosed example embodiments according to the inventive concepts. Further, it will be easily understood that the purposes and advantages according to one or more of the example embodiments of the inventive concepts may be realized as shown in the claims and combinations thereof.

According to at least one example embodiment of the inventive concepts, an apparatus for dicing a wafer includes a stage configured to receive a wafer, and move the wafer in a first direction, a plurality of laser heads above the stage along the first direction, and as the stage moves the wafer in the first direction, the plurality of laser heads are configured to emit a plurality of laser beams onto the wafer along a plurality of cutting lines, the plurality of cutting lines extending in the first direction and each cutting line spaced apart from other cutting lines in a second direction, the second direction perpendicular to the first direction.

According to at least one example embodiment of the inventive concepts, an apparatus for dicing a wafer includes a stage configured to receive a wafer, and move the wafer in a first direction, a plurality of laser heads, each of the plurality of laser heads including, an optical system, a height sensor configured to generate height data based on a height from a first surface of the wafer to the laser head, and a camera configured to generate image data based on an image of the wafer, and as the stage moves the wafer in the first direction, the plurality of optical systems are configured to emit a plurality of laser beam into the wafer along a plurality of cutting lines, each of the plurality of cutting lines extending in the first direction and spaced apart from each other in a second direction perpendicular to the first direction.

According to at least one example embodiment of the inventive concepts, an apparatus for dicing a wafer includes a stage configured to receive a wafer, and move the wafer in a first direction, and a plurality of laser heads arranged in the first direction, each of the plurality of laser heads including, an optical system, a height sensor configured to generate height data by measuring a height from a first surface of the wafer to the laser head, and a camera configured to generate image data by imaging the wafer, and wherein as the stage moves in the first direction, the optical system of each of the plurality of laser heads are each configured to emit a laser beam into the wafer along a respective cutting line of a plurality of cutting lines associated with the wafer, the plurality of cutting lines extending in the first direction and arranged in a second direction perpendicular to the first direction, and a plurality of optical axes corresponding to the plurality of laser heads respectively encounter different cutting lines among the plurality of cutting lines.

Specific details of the example embodiments are included in detailed descriptions and drawings.

### BRIEF DESCRIPTION OF DRAWINGS

The above and other aspects and features of various example embodiments of the inventive concepts will become more apparent by describing in detail the attached drawings, in which:

FIG. 1 and FIG. 2 are diagrams for illustrating an apparatus for dicing a wafer in accordance with some example embodiments;

FIG. 3 is a diagram for illustrating the apparatus for dicing the wafer in FIG. 1 and FIG. 2 according to at least one example embodiment;

FIG. 4 is a diagram for illustrating the apparatus for dicing the wafer in FIG. 1 and FIG. 2 according to at least one example embodiment;

FIG. 5 is a diagram for illustrating the apparatus for dicing the wafer in FIG. 1 and FIG. 2 according to at least one example embodiment;

FIG. 6 is a diagram for illustrating the apparatus for dicing the wafer in accordance with some example embodiments of FIG. 1 and FIG. 2;

FIG. 7 is a diagram for illustrating the apparatus for dicing the wafer in FIG. 1 and FIG. 2 according to at least one example embodiment;

FIG. 8 is a diagram for illustrating an apparatus for dicing a wafer according to some example embodiments;

FIG. 9 is a diagram for illustrating an apparatus for dicing a wafer according to some example embodiments;

FIG. 10 is a diagram for illustrating a first laser head in FIG. 9 according to at least one example embodiment; and

FIG. 11 is a diagram for illustrating the first laser head in FIG. 9 according to at least one example embodiment.

### DETAILED DESCRIPTION

Hereinafter, various example embodiments according to the inventive concepts will be described with reference to the attached drawings.

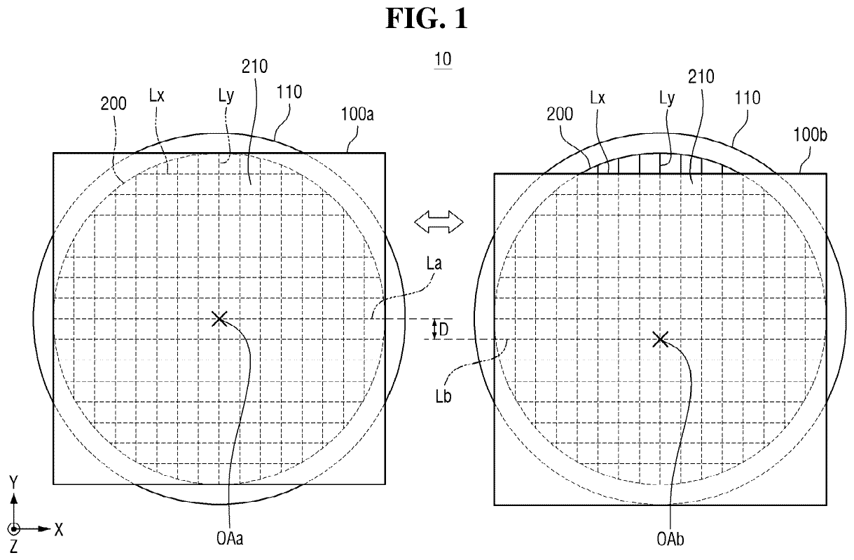

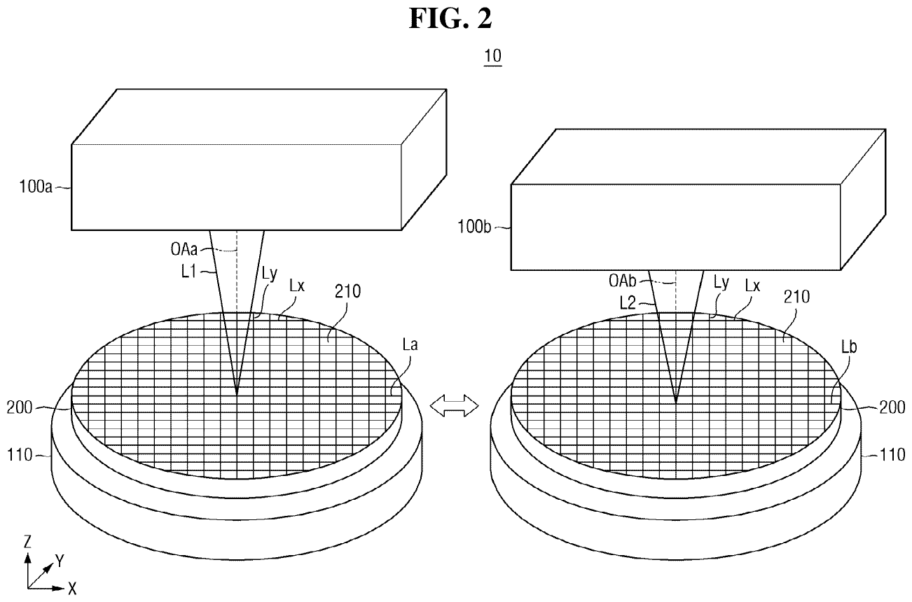

FIG. 1 and FIG. 2 are diagrams for illustrating an apparatus for dicing a wafer in accordance with some example embodiments.

Referring to FIG. 1 and FIG. 2, an apparatus 10 for dicing a wafer according to some example embodiments includes at least one stage 110, a plurality of laser heads, e.g., a first laser head 100a, and/or a second laser head 100b, etc., but the example embodiments are not limited thereto, and for example, the apparatus 10 may include a greater or lesser number of constituent components, for example, three or more laser heads, a single laser head, etc.

A wafer 200 includes one or more integrated circuit areas 210 and one or more first cutting lines Lx and one or more second cutting lines Ly that separate the integrated circuit areas 210 from each other. The first cutting lines Lx extend in a first direction X and are arranged in a second direction Y. The second cutting lines Ly extend in the second direction Y and are arranged in the first direction X. The integrated circuit areas 210 may be separated into a plurality of semiconductor chips using a dicing process performed along the first cutting lines Lx and the second cutting lines Ly. As shown in FIG. 1, the second direction Y is perpendicular to the first direction X.

The wafer 200 may be loaded onto a stage 110. The stage 110 may move in the first direction X, the second direction Y, and/or a third direction Z. The stage 110 may be rotatable on a plane including the first direction X and the second direction Y. As shown in FIGS. 1 and 2, the third direction Z is perpendicular to the first direction X and the second direction Y.

The apparatus 10 for dicing a wafer may cut the wafer 200 while moving a relative position between the wafer 200 and each of the first and second laser heads 100a and 100b. For example, while each of a position of the first laser head 100a and a position of the second laser head 100b is fixed, the stage 110 may receive the wafer 200 and move in a direction, such as the first direction X, thereby moving the wafer 200 so that the wafer 200 may be cut along the cutting lines Lx and Ly. Hereinafter, an example in which the stage 110 moves in the first direction X while the position of each of the first laser head 100a and the second laser head 100b is fixed will be described, but the example embodiments are not limited thereto, and for example, the stage 110 may move, for example, in the second direction Y, and/or the first and/or the second laser heads 100a and/or 100b may move, etc.

The first laser head 100a and the second laser head 100b may be positioned on top of the stage 110 in the third direction and may respectively radiate, transmit, and/or emit laser beams L1 and L2 downwardly toward the wafer 200 on the stage 110. The first laser head 100a and the second laser head 100b are arranged in the first direction X, but are not limited thereto.

According to at least one example embodiment, the first laser head 100a and the second laser head 100b may radiate, transmit, and/or emit laser beams toward different cutting lines, respectively. For example, an optical axis OAa of the first laser head 100a may encounter the first-first cutting line La, and an optical axis OAb of the second laser head 100b may encounter the first-second cutting line Lb, etc. As the stage 110 moves in the first direction X, the first laser head 100a may radiate, transmit, and/or emit the first laser beam L1 onto and/or into the wafer 200 along the first cutting line La, but is not limited thereto (e.g., the first laser beam L1 may be emitted onto a top surface of the wafer 200 and/or into an interior area of the wafer 200 below the top surface of the wafer 200 and above a bottom surface of the wafer 200). Subsequently, as the stage 110 moves in the first direction X, the second laser head 100b may radiate, transmit, and/or emit the second laser beam L2 onto and/or into the wafer 200 along the first-second cutting line Lb, but is not limited thereto. That is, as the stage 110 moves in the first direction X, the laser beams L1 and L2 may be irradiated, transmitted, and/or emitted onto the wafer 200 along the first-first cutting line La and the first-second cutting line Lb, respectively, etc.

A distance D in the second direction Y between the optical axis OAa of the first laser head 100a and the optical axis OAb of the second laser head 100b may be an integer multiple of a spacing between adjacent lines of the first cutting lines Lx. For example, the distance D in the second direction Y between the optical axis OAa of the first laser head 100a and the optical axis OAb of the second laser head 100b is a desired distance in the second direction Y between a first-first cutting line La and a first-second cutting line Lb, and may be equal to the spacing between adjacent cutting lines of the first cutting lines Lx, but the example embodiments are not limited thereto. When sizes of the first laser head 100a and the second laser head 100b are the same as each other, an extension line in the first direction X of a side wall in the second direction Y of the first laser head 100a may be spaced apart by the distance D from a side wall in the second direction Y of the second laser head 100b. Alternatively, and/or additionally, a plurality of first cutting lines may be positioned between the first-first cutting line La that the optical axis OAa of the first laser head 100a encounters and the first-second cutting line Lb that the optical axis OAb of the second laser head 100b encounters, but the example embodiments are not limited thereto.

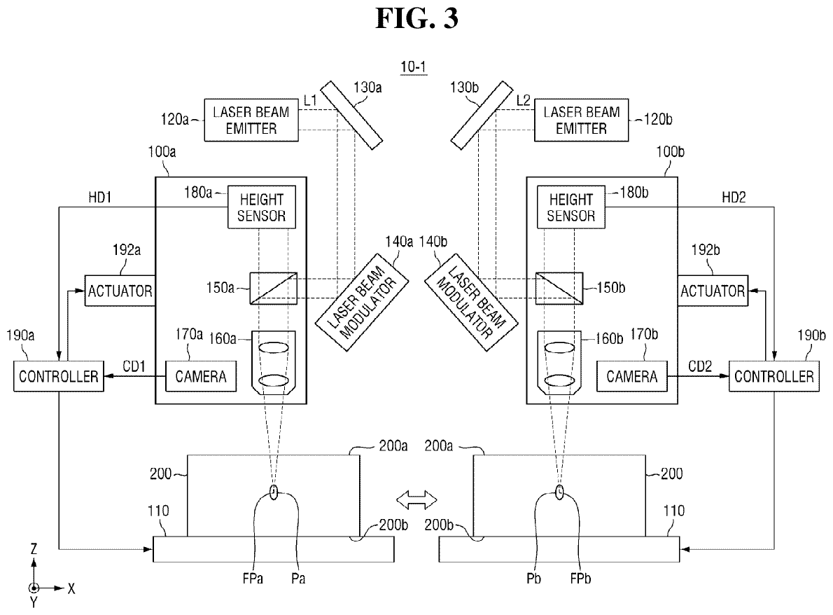

FIG. 3 is a diagram for illustrating the apparatus for dicing the wafer in FIG. 1 and FIG. 2 according to at least one example embodiment.

Referring to FIG. 3, an apparatus 10-1 for dicing a wafer according to some example embodiments includes the at least one stage 110, the first laser head 100a, the second laser head 100b, a first laser beam emitter 120a, a second laser beam emitter 120b, a first transfer optics 130a, a second transfer optics 130b, a first laser beam modulator 140a, a second laser beam modulator 140b, a first controller 190a, a second controller 190b, a first actuator 192a, and/or a second actuator 192b, etc., but the example embodiments are not limited thereto, and for example, there may be a greater or lesser number of laser heads, laser beam emitters, transfer optics, laser beam modulators, controllers, and/or actuators, etc., included in the wafer dicing apparatus.

In the apparatus 10-1 for dicing a wafer according to some example embodiments, the first and second laser heads 100a and 100b may receive the laser beams L1 and L2 from different laser beam emitters, respectively. The first laser head 100a may receive the first laser beam L1 from the first laser beam emitter 120a, while the second laser head 100b may receive the second laser beam L2 from the second laser beam emitter 120b.

Each of the first and second laser beam emitters 120a and 120b may include at least one light source. Depending on design considerations, such as a material, a thickness, etc., of the wafer 200, etc., a wavelength, a pulse width, an output power, etc., of each of the first and second laser beams L1 and L2 output from each of the first and second laser beam emitters 120a and 120b may be adjusted.

The first laser beam modulator 140a may be positioned between the first laser beam emitter 120a and the first laser head 100a. The first laser beam modulator 140a may modulate and/or adjust the first laser beam L1.

The second laser beam modulator 140b may be positioned between the second laser beam emitter 120b and the second laser head 100b. The second laser beam modulator 140b may modulate and/or adjust the second laser beam L2.

Each of the first and second laser beam modulators 140a and 140b may modulate and/or adjust at least one of a shape and/or a phase of each of the first and second laser beams L1 and L2, but are not limited thereto. Each of the first and second laser beam modulators 140a and 140b may be, for example, a spatial light modulator (SLM), etc.

The first transfer optics 130a may be positioned between the first laser beam emitter 120a and the first laser head 100a. The first transfer optics 130a may transfer and/or reflect the first laser beam L1 to the first laser beam modulator 140a, or may transfer and/or reflect the modulated first laser beam L1 to the first laser head 100a. For example, the first transfer optics 130a may be positioned between the first laser beam emitter 120a and the first laser beam modulator 140a, and may reflect the first laser beam L1 output thereto from the first laser beam emitter 120a toward the first laser beam modulator 140a, but is not limited thereto.

The second transfer optics 130b may be positioned between the second laser beam emitter 120b and the second laser head 100b. The second transfer optics 130b may transfer and/or reflect the second laser beam L2 to the second laser beam modulator 140b, or may transfer and/or reflect the modulated second laser beam L2 to the second laser head 100b. For example, the second transfer optics 130b may be positioned between the second laser beam emitter 120b and the second laser beam modulator 140b, and may reflect the second laser beam L2 output thereto from the second laser beam emitter 120b toward the second laser beam modulator 140b, but is not limited thereto.

Each of the first and second transfer optics 130a and 130b may be embodied as various optical elements, such as a mirror, a lens, etc. The number and the arrangement of the optical elements included in each of the first and second transfer optics 130a and 130b are not limited thereto and may vary.

The first and second laser heads 100a and 100b respectively include beam splitters 150a and 150b, optical systems 160a and 160b, cameras 170a and 170b, and/or height sensors 180a and 180b, etc., but are not limited thereto. The first laser head 100a includes the first beam splitter 150a, the first optical system 160a, the first camera 170a, and/or the first height sensor 180a, etc. The second laser head 100b includes the second beam splitter 150b, the second optical system 160b, the second camera 170b, and/or the second height sensor 180b, etc. The second laser head 100b may have a similar structure to that of the first laser head 100a, but the example embodiments are not limited thereto.

The first beam splitter 150a may be positioned between the first optical system 160a and the first height sensor 180a. The first beam splitter 150a may reflect at least a portion of the modulated first laser beam L1 and provide the modulated first laser beam L1 to the first optical system 160a. The first beam splitter 150a may include, for example, a half mirror, etc., but is not limited thereto.

The first optical system 160a may be positioned between the wafer 200 and the first beam splitter 150a. The first optical system 160a may focus the modulated first laser beam L1 onto and/or into the wafer 200 (e.g., the first laser beam L1 may be emitted onto the surface of the wafer 200 and/or into an interior area of the wafer 200 below a top surface of the wafer 200 and above a bottom surface of the wafer 200). For example, the modulated first laser beam L1 may be focused on a first focusing point FPa, but is not limited thereto. Accordingly, a first modified area Pa may be formed within and/or on the wafer 200. The first modified area Pa may be an area where cracks, cuts, etc., in the wafer occur. The first optical system 160a may include, for example, an objective lens, but is not limited thereto.

As the stage 110 moves in the first direction X, the first modified areas Pa within the wafer 200 may be formed along the first-first cutting line La. When the first modified areas Pa have been formed, balance of intermolecular forces in the wafer 200 may be lost. Thus, when an external force is applied to the wafer 200, the wafer 200 may start to be divided (e.g., divided naturally) along the first modified areas Pa.

The first height sensor 180a may generate first height data HD1 by detecting a height of a first surface 200a of the wafer 200, that is, a position of the first surface 200a of the wafer 200 along the third direction Z. For example, the first height sensor 180a may generate the first height data HD1 based on a measuring result of a distance between the first surface 200a of the wafer 200 and the first laser head 100a. The first height sensor 180a may provide the first height data HD1 to the first controller 190a. Alternatively, or additionally, the first height sensor 180a may determine a height at a reference position as a reference value and determine a height at another position based on a difference of the first surface 200a of the wafer 200 from the reference value.

The wafer 200 may include the first surface 200a and a second surface 200b, which are opposite to each other in the third direction Z. The second surface 200b may be an active surface on which a semiconductor device is formed, and the first surface 200a may be an inactive surface, but the example embodiments are not limited thereto.

The first camera 170a may generate first image data CD1 by imaging the first surface 200a of the wafer 200. The first camera 170a may provide the first image data CD1 to the first controller 190a. The first camera 170a may be embodied as a vision camera, optical camera, etc., but is not limited thereto.

The first controller 190a may control the first laser head 100a, the stage 110, and/or the first actuator 192a, etc., but is not limited thereto. According to some example embodiments, the first controller 190a may be implemented as processing circuitry and may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The first controller 190a may perform focusing (e.g., auto focusing) to adjust (e.g., automatically adjust) a position of the first focusing point FPa based on the first height data HD1. The first controller 190a may generate at least one control signal to control at least one of the first actuator 192a and the stage 110 based on the first height data HD1. The first actuator 192a and the stage 110 may move in the third direction Z based on the control signal from the first controller 190a.

For example, the first controller 190a may adjust the position and/or location of the first focusing point FPa on the wafer 200 by adjusting a distance between the first actuator 192a and the wafer 200. The first controller 190a may control at least one of the first actuator 192a and the stage 110 to adjust the position of the first focusing point FPa. The first actuator 192a may adjust the position of the first laser head 100a in the third direction Z based on the control signal from the first controller 190a. The first actuator 192a may adjust the position of the stage 110 in the third direction Z based on the control signal from the first controller 190a.

In another example, the first controller 190a may control the first optical system 160a to adjust the position and/or location of the first focusing point FPa on the wafer 200. For example, the first actuator 192a may adjust the position of the first optical system 160a in the third direction Z based on the control signal from the first controller 190a.

The first controller 190a may align the wafer 200 and the first laser head 100a with each other based on the first image data CD1. The first controller 190a may generate at least one control signal to control at least one of the first actuator 192a and/or the stage 110 based on the first image data CD1. For example, the first actuator 192a and/or the stage 110 may be moved in the first direction X and/or the second direction Y based on the control signal of the first controller 190a. Accordingly, the wafer 200 and the first laser head 100a may be aligned with each other.

The first controller 190a may be implemented as hardware or a combination of hardware and firmware and/or software. For example, the first controller 190a may be a computing device, such as a workstation computer, a desktop computer, a laptop computer, a server, and/or a tablet computer, etc. For example, the controller 190a may include a memory device, such as ROM (Read Only Memory) and RAM (Random Access Memory) in which various programming instructions and/or computer readable instructions are stored, and processing circuitry, such as at least one processor, microprocessor, CPU (Central Processing Unit), and/or GPU (Graphics Processing Unit), etc., configured to process the programming instructions and/or computer readable instructions stored in the memory device, and a signal provided from an external source.

The second beam splitter 150b may be positioned between the second optical system 160b and the second height sensor 180b. The second beam splitter 150b may reflect at least a portion of the modulated second laser beam L2 and may provide the modulated first laser beam L1 to the second optical system 160b. Since the second beam splitter 150b is similar to the first beam splitter 150a, detailed description thereof is omitted.

The second optical system 160b may be positioned between the wafer 200 and the second beam splitter 150b. The second optical system 160b may focus the modulated second laser beam L2 onto and/or into the wafer 200. The modulated second laser beam L2 may be focused on a second focusing point FPb. Accordingly, a second modified area Pb within the wafer 200 may be formed. The second modified area Pb may be an area where cracks occur and/or are formed in the wafer 200. As the stage 110 moves in the first direction X, the second modified areas Pb within the wafer 200 may be formed along the first-second cutting line Lb. Since the second optical system 160b is similar to the first optical system 160a, detailed description thereof is omitted.

The second height sensor 180b may generate second height data HD2 by detecting a height of the first surface 200a of the wafer 200, that is, a position of the first surface 200a of the wafer 200 along the third direction Z, but is not limited thereto. The second height sensor 180b may provide the second height data HD2 to the second controller 190b. Since the second height sensor 180b is similar to the first height sensor 180a, a detailed description thereof is omitted.

The second camera 170b may generate second image data CD2 by imaging the first surface 200a of the wafer 200. The second camera 170b may provide the second image data CD2 to the second controller 190b. Since the second camera 170b is similar to the first camera 170a, detailed description thereof is omitted.

The second controller 190b may control the second laser head 100b, the stage 110, and/or the second actuator 192b, etc., but is not limited thereto. According to some example embodiments, the second controller 190b may be implemented as processing circuitry and may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The second controller 190b may perform focusing (and/or auto focusing) to adjust (and/or automatically adjust) a position and/or location of the second focusing point FPb based on the second height data HD2. The second controller 190b may generate at least one control signal to control at least one of the second actuator 192b and/or the stage 110 based on the second height data HD2. The second actuator 192b and/or the stage 110 may move in the third direction Z based on the control signal from the second controller 190b.

The second controller 190b may align the wafer 200 and the second laser head 100b with each other based on the second image data CD2. The second controller 190b may generate at least one control signal to control at least one of the second actuator 192b and/or the stage 110 based on the second image data CD2. The second actuator 192b and/or the stage 110 may move in the first direction X and/or the second direction Y based on the control signal from the second controller 190b. Accordingly, the wafer 200 and the second laser head 100b may be aligned with each other. The second controller 190b is similar to the first controller 190a. Thus, detailed descriptions thereof are omitted.

The first controller 190a may control the first actuator 192a so that the optical axis OAa of the first laser head 100a encounters the first-first cutting line La. The second controller 190b may control the second actuator 192b so that the optical axis OAb of the second laser head 100b encounters the first-second cutting line Lb. The distance D in the second direction Y between the optical axis OAa of the first laser head 100a and the optical axis OAb of the second laser head 100b may be controlled by the first controller 190a and/or the second controller 190.

Thereafter, as the stage 110 moves in the first direction X, the first modified areas Pa may be formed along the first-first cutting line La, and the second modified areas Pb may be formed along the first-second cutting line Lb, etc.

In the drawing, the first controller 190a and the second controller 190b are shown as separate controllers. However, the example embodiments of the inventive concepts are not limited thereto, and for example, the first controller 190a and the second controller 190b may be integrated into one controller or three or more controllers, may be external to the apparatus 10 (e.g., the controller(s) may be implemented in a computer communicatively connected to the apparatus 10), etc.

The wafer cutting device according to some example embodiments may form the first and second modified areas Pa and Pb within the wafer 200 along the two cutting lines La and Lb as the stage 110 scans a path in the first direction X once, but the example embodiments are not limited thereto.

Additionally, a one-time scan speed of the wafer 200 may be increased from 0, may converge to a desired and/or certain speed, and then may be decreased to 0, etc., by the first controller 190a and/or the second controller 190b of the apparatus 10. When the modified areas are formed within the wafer 200 along two cutting lines, respectively, using a wafer cutting apparatus that forms a modified area within the wafer 200 along one cutting line at a one-time scan, there are two periods for which the scan speed increases and two periods where the scan speed decreases. However, when the wafer cutting apparatus according to some example embodiments is used to form the modified areas within the wafer 200 along the two cutting lines, there is one period for which the scan speed increases and one period where the scan speed decreases.

Therefore, a time desired and/or required to cut the wafer 200 may be reduced and productivity may be improved.

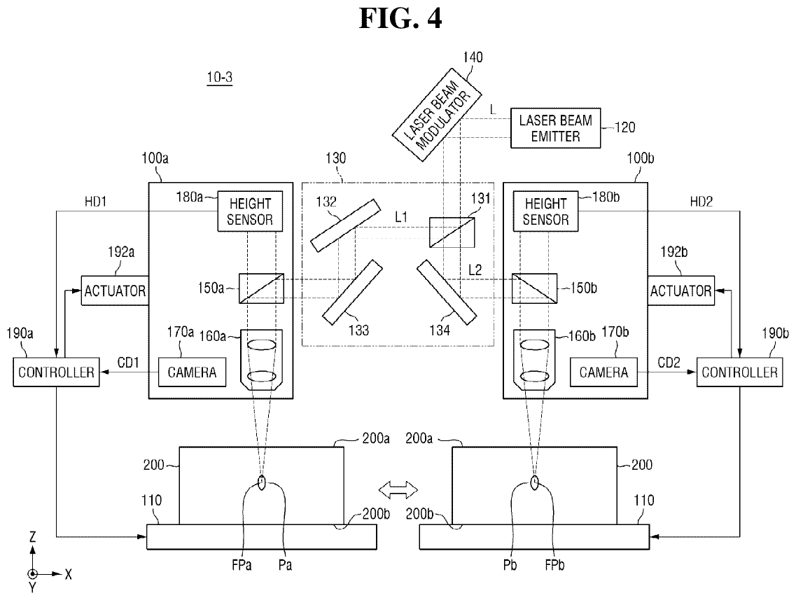

FIG. 4 is a diagram for illustrating the apparatus for dicing the wafer in FIG. 1 and FIG. 2 according to at least one example embodiment. For the sake of brevity and clarity, the following discussions mainly describe differences between the example embodiment(s) of FIG. 4 and the example embodiments of FIG. 1 to FIG. 3.

Referring to FIG. 4, an apparatus 10-2 for dicing a wafer according to some example embodiments includes the stage 110, the first laser head 100a, the second laser head 100b, a laser beam emitter 120, a transfer optics 130, a laser beam modulator 140, the first controller 190a, the first actuator 192a, the second controller 190b, and/or the second actuator 192b, etc., but the example embodiments are not limited thereto. The first and second laser heads 100a and 100b may share each of the laser beam emitter 120 and the laser beam modulator 140 with each other, but are not limited thereto.

The laser beam emitter 120 may output a laser beam L. The laser beam modulator 140 may modulate and/or adjust the laser beam L. The transfer optics 130 may split the modulated laser beam L into first and second laser beams L1 and L2, and may provide and/or reflect the first laser beam L1 to the first laser head 100a, and may provide and/or reflect the second laser beam L2 to the second laser head 100b, etc., but is not limited thereto.

For example, the transfer optics 130 may include a beam splitter 131 and a plurality of mirrors, such as mirrors 132, 133, and 134, etc., but is not limited thereto. The beam splitter 131 may reflect and/or split a portion (e.g., a first portion) of the modulated laser beam L toward the mirror 132 as the first laser beam L1 (e.g., a first split laser beam, etc.) and may transmit (e.g., pass through) a remainder portion (e.g., a second portion) of the laser beam L toward the mirror 134 as the second laser beam L2 (e.g., a second split laser beam, etc.). The mirrors 132 and 133 may reflect the first laser beam L1 toward the first laser head 100a, and the mirror 134 may reflect the second laser beam L2 toward the second laser head 100b.

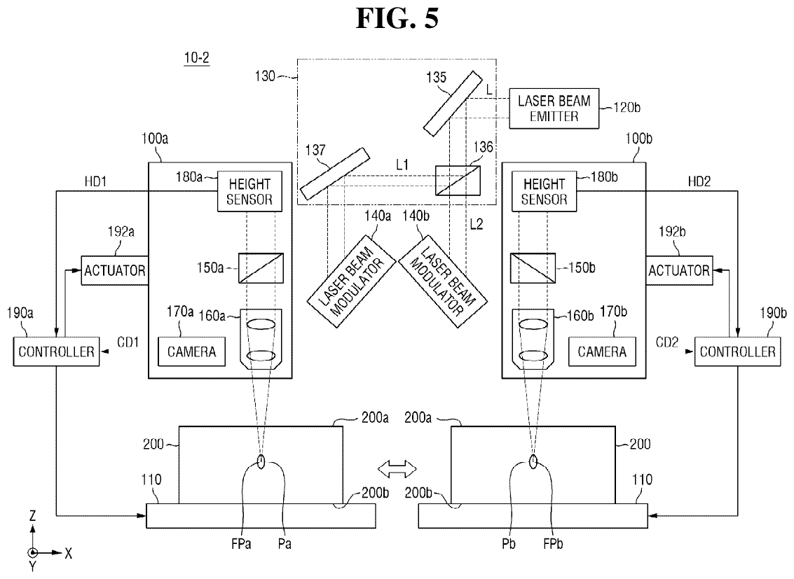

FIG. 5 is a diagram for illustrating the apparatus for dicing the wafer in FIG. 1 and FIG. 2 according to at least one example embodiment. For the sake of clarity and brevity, the following discussion mainly describe differences between the at least one example embodiment of FIG. 5 and the example embodiments of FIG. 1 to FIG. 4.

Referring to FIG. 5, an apparatus 10-3 for dicing a wafer according to some example embodiments includes the stage 110, the first laser head 100a, the second laser head 100b, the laser beam emitter 120, the transfer optics 130, the first laser beam modulator 140a, the second laser beam modulator 140b, the first controller 190a, the first actuator 192a, the second controller 190b, and/or the second actuator 192b, etc. The first and second laser heads 100a and 100b may share the laser beam emitter 120 with each other, but are not limited thereto.

The transfer optics 130 may split the laser beam L into the first and second laser beams L1 and L2, and may provide the first laser beam L1 to the first laser beam modulator 140a, and may provide the second laser beam L2 to the second laser beam modulator 140b.

For example, the transfer optics 130 may include a plurality of mirrors, e.g., mirrors 135 and 137, etc., and a beam splitter 136, but is not limited thereto. The mirror 135 reflects the laser beam L to the beam splitter 136. The beam splitter 136 may reflect a portion (e.g., a first portion) of the laser beam L toward the mirror 137 as the first laser beam L1 (e.g., a first split laser beam, etc.) and may transmit (e.g., pass through) a remaining portion (e.g., a second portion) of the laser beam L toward the second laser beam modulator 140b as the second laser beam L2 (e.g., a second split laser beam, etc.). The mirror 137 may reflect the first laser beam L1 to the first laser beam modulator 140a.

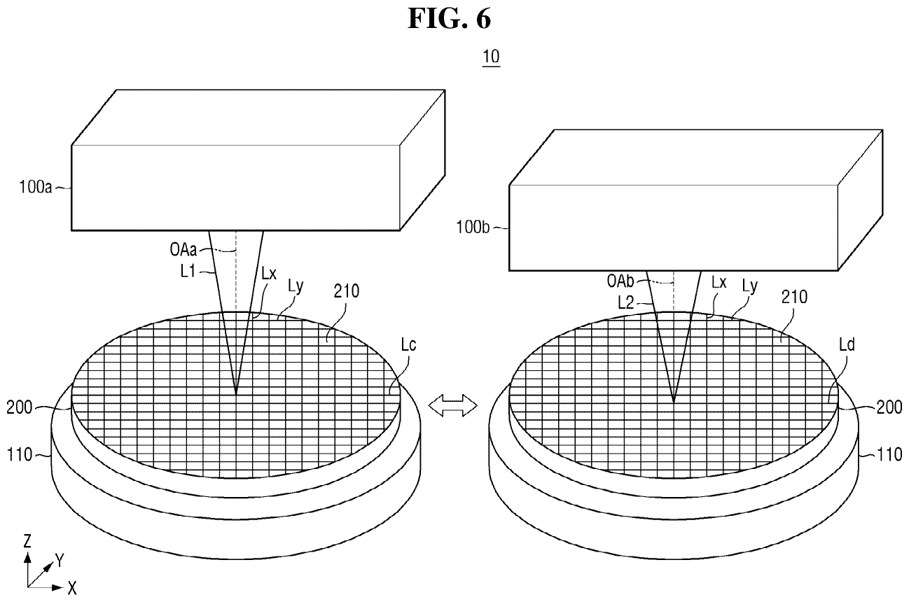

FIG. 6 is a diagram for illustrating an apparatus for dicing the wafer in accordance with some example embodiments of FIG. 1 and FIG. 2. For the sake of clarity and brevity, the following discussion mainly describe the differences between the at least one example embodiment of FIG. 6 and the example embodiments of FIG. 1 to FIG. 5.

Referring to FIG. 1 and FIG. 2, as the stage 110 moves in the first direction X, the first laser head 100a radiate, transmit, and/or emit the first laser beam LI to the wafer 200 along the first-first cutting line La, and then, the second laser head 100b may radiate, transmit, and/or emit the second laser beam L2 to the wafer 200 along the first-second cutting line Lb.

Next, referring to FIG. 6, the stage 110 may rotate by a desired amount, such as 90 degrees, etc., but is not limited thereto (e.g., the stage 110 may rotate the wafer 200 by 90 degrees, 180 degrees, 270 degrees, etc.). Accordingly, the first cutting lines Lx may extend in the second direction Y and a plurality of second cutting line Ly (e.g., a plurality of secondary cutting lines, etc.) may extend in the first direction X. The optical axis OAa of the first laser head 100a may encounter a second-first cutting line Lc as one of the plurality of second cutting lines Ly, while the optical axis OAb of the second laser head 100b may encounter a second-second cutting line Ld which is one of the plurality of second cutting lines Ly, but are not limited thereto.

Subsequently, the stage 110 may move in a direction opposite to the first direction X. As the stage 110 moves in the opposite direction to the first direction X, the second laser head 100b may radiate, transmit, and/or emit the second laser beam L2 to the wafer 200 along the second-second cutting line Ld and then, the first laser head 100a may radiate, transmit, and/or emit the first laser beam L1 to the wafer 200 along the second-first cutting line Lc.

Alternatively, or additionally, after radiating, transmitting, and/or emitting the laser beams L1 and L2 along the first and second cutting lines La and Lb, respectively, a relative position between the stage 100 and the first laser head 100a may be changed, and a relative position between the stage 100 and the second laser head 100b may be changed, such that the optical axis OAa of the first laser head 100a and the optical axis OAb of the second laser head 100b respectively encounter different first cutting lines Lx.

Then, the stage 100 may move in the opposite direction to the first direction X. As the stage 100 moves in the direction opposite to the first direction X, the second laser beam L2 may be radiated, transmitted, and/or emitted to the wafer 200 along a first cutting line Lx that the optical axis OAb of the second laser head 100b encounters, and subsequently, the first laser beam L1 may be radiated, transmitted, and/or emitted to the wafer 200 along a first cutting line Lx that the optical axis OAa of the first laser head 100a encounters.

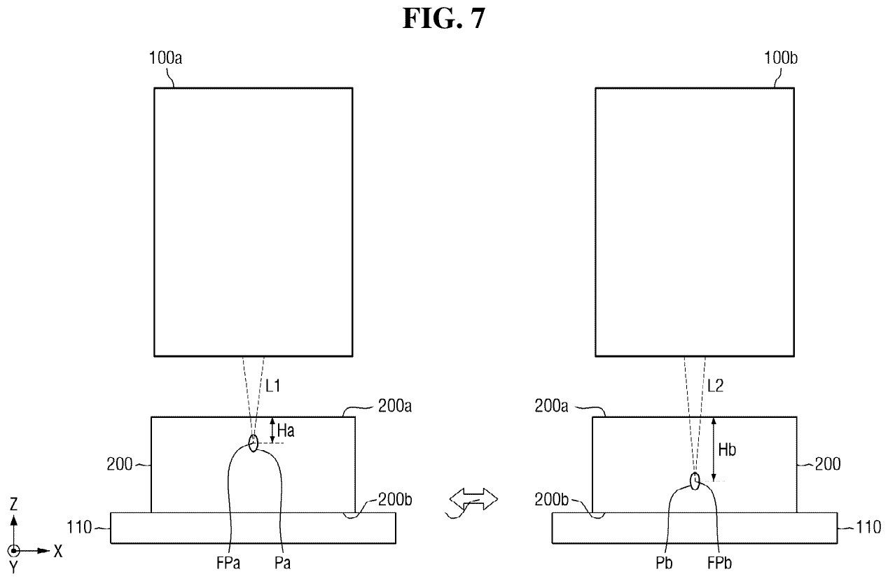

FIG. 7 is a diagram for illustrating the apparatus for dicing the wafer in FIG. 1 and FIG. 2. For the sake of clarity and brevity, the following discussion mainly describe differences between the at least one example embodiment of FIG. 7 and the example embodiments of FIGS. 1 to 6.

Referring to FIG. 7, in the apparatus for dicing a wafer according to some example embodiments, the first focusing point FPa of the first laser head 100a and the second focusing point FPb of the second laser head 100b may be positioned at different positions and/or locations spaced from the first surface 200a of the wafer 200 by different spacings, e.g., different distances.

The first focusing point FPa may be formed at a first depth Ha (e.g., a first distance, etc.) from the first surface 200a of the wafer 200, and the second focusing point FPb may be formed at a second depth Hb (e.g., a second distance) from the first surface 200a of the wafer 200. The first depth Ha and the second depth Hb may be different from each other, but are not limited thereto. The first laser head 100a may radiate, transmit, and/or emit the first laser beam L1 to the first focusing point FPa, and the second laser head 100b may radiate, transmit, and/or emit the second laser beam L2 to the second focusing point FPb. According to some example embodiments, the first focusing point FPa and/or the second focusing point FPb may be located at and/or resolve at a location inside the wafer 200 and/or below a first surface 200a of the wafer 200 and a second surface 200b of the wafer 200, etc. Accordingly, the first laser head 100a and the second laser head 100b may respectively form the first and second modified areas Pa and Pb at different depths.

For example, the optical axis OAa of the first laser head 100a and the optical axis OAb of the second laser head 100b may respectively encounter different cutting lines. The first laser head 100a and the second laser head 100b may respectively form the modified areas Pa and Pb at different positions and along different cutting lines, but are not limited thereto. In another example, the optical axis OAa of the first laser head 100a and the optical axis OAb of the second laser head 100b may encounter the same cutting line. The first laser head 100a and the second laser head 100b may respectively form the modified areas Pa and Pb at different positions and along the same cutting line, but are not limited thereto.

FIG. 7 is a diagram showing some components (e.g., the wafer 200, the stage 110, the first and second laser heads 100a and 100b) of the apparatus for dicing the wafer, but is not limited thereto. The apparatus for dicing the wafer in FIG. 7 may be one of the apparatuses for dicing the wafer in FIGS. 3 to 5, but is not limited thereto.

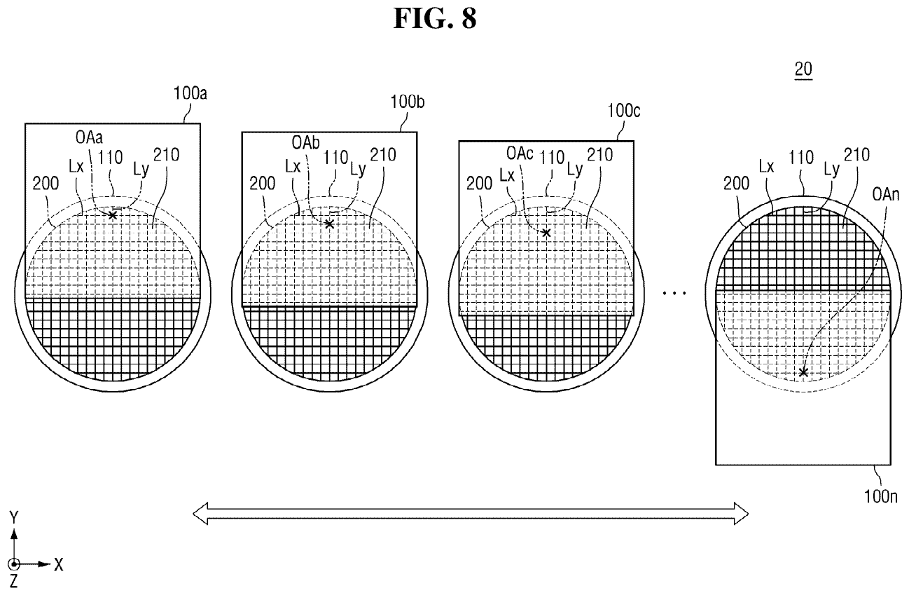

FIG. 8 is a diagram for illustrating an apparatus for dicing a wafer according to some example embodiments. For the sake of clarity and brevity, the following discussion mainly describes differences between the at least one example embodiment of FIG. 8 and the example embodiments of FIGS. 1 to 7.

Referring to FIG. 8, an apparatus 20 for dicing a wafer according to some example embodiments includes a plurality of laser heads 100a to 100n (where n is a natural number of 3 or larger).

Each of first to n-th laser heads 100a to 100n may be disposed on top of the stage 110 and may radiate, transmit, and/or emit laser beams downwardly toward the wafer 200 on the stage 110.

The first to n-th laser heads 100a to 100n may be arranged in the first direction X, but are not limited thereto. The first to n-th laser heads 100a to 100n may respectively radiate, transmit, and/or emit the laser beams to different cutting lines. Optical axes OAa to OAn of the first to n-th laser heads 100a to 100n may encounter different first cutting lines Lx, respectively.

Spacings between neighboring ones of the optical axes OAa to OAn may be various (e.g., different), but are not limited thereto. As the stage 110 moves in the first direction, the first to n-th laser heads 100a to 100n may respectively radiate, transmit, and/or emit the laser beams to the wafer 200 along the different first cutting lines Lx.

The two neighboring laser heads among the first to n-th laser heads 100a to 100n may be the first and second laser heads 100a and 100b in each of FIGS. 3 to 5 and FIG. 7, and may be included in the apparatus for dicing the wafer in each of FIGS. 3 to 5 and FIG. 7, but are not limited thereto.

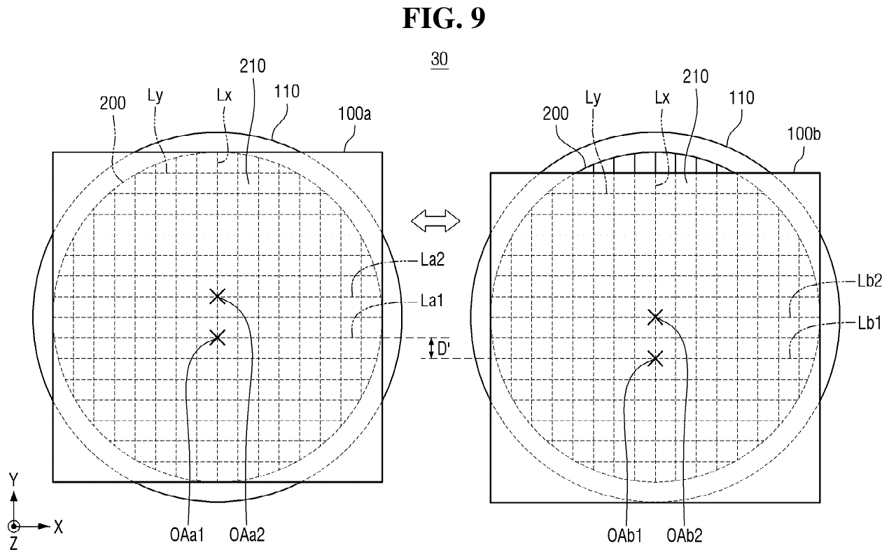

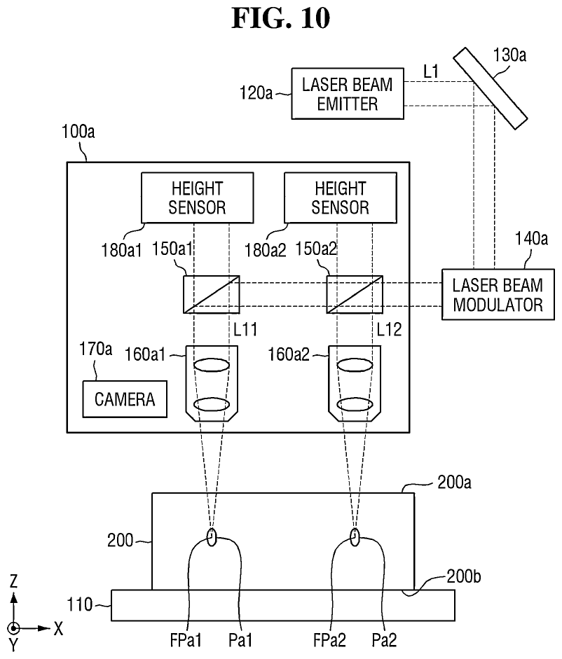

FIG. 9 is a diagram for illustrating an apparatus for dicing a wafer according to some example embodiments. FIG. 10 is a diagram for illustrating a first laser head in FIG. 9. For the sake of clarity and brevity, the following discussions mainly describe differences between the example embodiments of FIGS. 9 and 10 and the example embodiments of FIGS. 1 to 7.

Referring to FIG. 9, in an apparatus 30 for dicing a wafer according to some example embodiments, each of the plurality of laser heads, e.g., the first laser head 100a and the second laser head 100b, etc., may include a plurality of optical systems.

Referring to FIG. 9 and FIG. 10, the first laser head 100a may include a first-first beam splitter 150a1, a first-second beam splitter 150a2, a first-first optical system 160a1, a first-second optical system 160a2, a first-first height sensor 180a1, a first-second height sensor 180a2, and/or a first camera 170a, etc.

The first-second beam splitter 150a2 may reflect a portion (e.g., a first portion) of the first laser beam L1 toward the first-second optical system 160a2 as a first-second laser beam L12 (e.g., a first split laser beam, etc.), and may transmit (e.g., pass through) a remaining portion (e.g., a second portion) of the first laser beam L1 toward the first-first optical system 160a1 as a first-first laser beam L11 (e.g., a second split laser beam, etc.), etc.

An optical axis OAa1 of the first-first optical system 160a1 may encounter a first-first cutting line La1. An optical axis OAa2 of the first-second optical system 160a2 may encounter a first-second cutting line La2. The first-first optical system 160a1 may focus the first-first laser beam L11 onto a first-first focusing point FPa1. Accordingly, a first-first modified area Pa1 may be formed on and/or within the wafer 200. The first-second optical system 160a2 may focus the first-second laser beam L12 to a first-second focusing point FPa2. Accordingly, a first-second modified area Pa2 may be formed on and/or within the wafer 200.

As the stage 110 moves in the first direction X, the first-first optical system 160a1 may reflect, radiate, transmit, and/or emit the first laser beam L1 onto and/or into the wafer 200 along the first-first cutting line La1. The first-second optical system 160a2 may reflect, radiate, transmit, and/or emit the first laser beam L1 onto and/or into the wafer 200 along the first-second cutting line La2. That is, while the wafer 200 is moved while under the first laser head 100a, the first laser beam L1 may be reflected, irradiated, transmitted, and/or emitted onto and/or into the wafer 200 along the two first cutting lines La1 and La2. Accordingly, the first-first modified areas Pa1 and the first-second modified areas Pa2 may be formed and/or created within the wafer 200.

In some example embodiments, a depth (e.g., distance and/or height) of the first-first focusing point FPa1 from the first surface 200a of the wafer 200 may be equal to a depth (e.g., distance and/or height) of the first-second focusing point FPa2 from the first surface 200a of the wafer 200. The first-first modified areas Pal and the first-second modified areas Pa2 may be positioned and/or located at the same depth based on the first surface 200a of the wafer 200, but are not limited thereto.

Each of the first-first height sensor 180a1 and the first-second height sensor 180a2 may detect the height of the first surface 200a of the wafer 200, that is, the position along the third direction Z. Unlike what is shown in the drawing, the first laser head 100a may include one height sensor.

FIG. 10 is a diagram showing some components of the apparatus for dicing wafers according to at least one example embodiment. As described above with reference to the apparatus for dicing the wafer in FIG. 3 to FIG. 5, the apparatus for dicing the wafer in FIG. 10 may include the first actuator 192a for moving the first laser head 100a and may further include the first controller 190a that controls the first laser head 100a and the stage 110, but the example embodiments are not limited thereto.

Referring again to FIG. 9, the second laser head 100b may have a similar structure to that of the first laser head 100a, but is not limited thereto. The second laser head 100b may include an optical system with an optical axis OAb1 and/or an optical system with an optical axis OAb2, but is not limited thereto. The optical axis OAb1 may encounter a second-first cutting line Lb1, and the optical axis OAb2 may encounter a second-second cutting line Lb2.

As the stage 110 moves in the first direction X, the second laser head 100b may radiate, transmit, and/or emit the laser beam onto and/or into the wafer 200 along the second-first cutting line Lb1 and the second-second cutting line Lb2. That is, while the wafer 200 is moved while under the first laser head 100a, the laser beam may be radiated, transmitted, and/or emitted onto and/or into the wafer 200 (e.g., onto the surface of the wafer 200 and/or into an interior area of the wafer 200 under a top surface of the wafer 200) along the two second cutting lines Lb1 and Lb2.

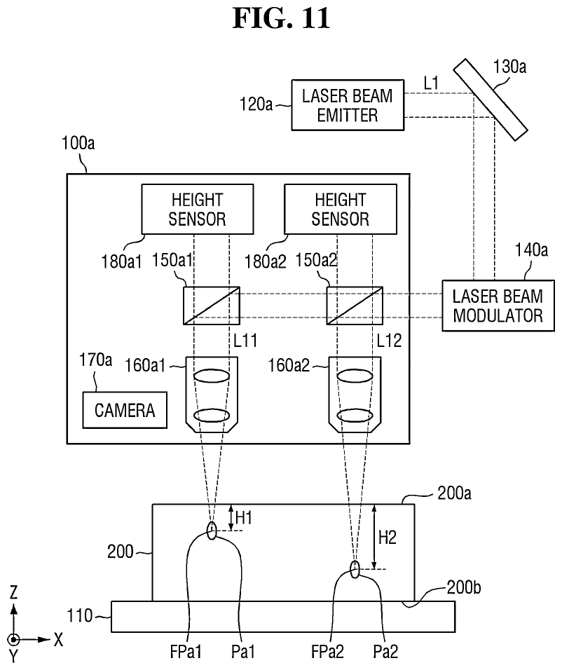

FIG. 11 is a diagram for illustrating the first laser head in FIG. 9 according to at least one example embodiment. For the sake of clarity and brevity, following discussion mainly describes differences between the at least one example embodiment of FIG. 11 and the example embodiments of FIG. 9 and FIG. 10.

Referring to FIG. 11, in the first laser head 100a according to some example embodiments, a depth H1 of the first-first focusing point FPa1 from the first surface 200a of the wafer 200 (e.g., the distance H1 between the first-first focusing point FPa1 and the first surface 200a) may be different from a depth H2 of the first-second focusing point FPa2 from the first surface 200a of the wafer 200 (e.g., the distance H2 between the first-second focusing point FPa2 and the first surface 200a). The first-first modified areas Pal and the first-second modified areas Pa2 may be positioned and/or located at different depths (e.g., distances, etc.) based on the first surface 200a of the wafer 200.

The second laser head 100b in FIG. 9 may have a similar structure to that of the first laser head 100a in FIG. 10 or the first laser head 100a in FIG. 11.

Although various example embodiments of the inventive concepts have been described with reference to the accompanying drawings, the example embodiments of the inventive concepts are not limited thereto, and may be implemented in various different forms. A person of ordinary skill in the art may appreciate that the inventive concepts may be practiced in other concrete forms without changing the technical spirit or essential characteristics of the inventive concepts. Therefore, it should be appreciated that the example embodiments as described above are not restrictive but illustrative in all respects.

What is claimed is:

1. An apparatus for dicing a wafer, the apparatus comprising:
a stage configured to receive a wafer, and move the wafer in a first direction; and
a plurality of laser heads above the stage along the first direction, and
as the stage moves the wafer in the first direction, the plurality of laser heads are configured to emit a plurality of laser beams onto the wafer along a plurality of cutting lines, the plurality of cutting lines extending in the first direction and each cutting line spaced apart from other cutting lines in a second direction, the second direction perpendicular to the first direction.

2. The apparatus of claim 1, wherein a distance in the second direction between optical axes of each of the plurality of laser heads is equal to a distance between each of the plurality of cutting lines.

3. The apparatus of claim 1, further comprising:
a plurality of laser beam emitters configured to output the plurality of laser beams.

4. The apparatus of claim 3, further comprising:
a plurality of laser beam modulators each disposed between a corresponding laser beam emitter of the plurality of laser beam emitters and a corresponding laser head of the plurality of laser heads.

5. The apparatus of claim 1, further comprising:
a laser beam emitter configured to output a laser beam; and
a beam splitter configured to split the laser beam into the plurality of laser beams.

6. The apparatus of claim 5, further comprising:
a laser beam modulator disposed between the laser beam emitter and the beam splitter.

7. The apparatus of claim 5, further comprising:
a plurality of laser beam modulators disposed between the beam splitter and the plurality of laser heads.

8. The apparatus of claim 1, wherein
the plurality of laser heads are configured to emit the plurality of laser beams to a plurality of depths below a first surface of the wafer, each of the plurality of depths being a different depth.

9. The apparatus of claim 1, wherein
each of the plurality of laser heads further includes a beam splitter configured to split a corresponding laser beam of the plurality of laser beams into a first split laser beam and a second split laser beam; and
as the stage moves the wafer in the first direction, each of the plurality of laser heads are configured to transmit the first split laser beam and the second split laser beam into the wafer along different cutting lines of the plurality of cutting lines.

10. The apparatus of claim 9, wherein each of the plurality of laser heads are configured to:
transmit the first split laser beam to a first depth from a first surface of the wafer; and
transmit the second split laser beam to a second depth from the first surface of the wafer, wherein the second depth is different from the first depth.

11. The apparatus of claim 1, wherein
the stage is further configured to rotate the wafer by 90 degrees; and
after the stage rotates the wafer by 90 degrees and the stage moves the wafer in the first direction, each of the plurality of laser heads are further configured to emit a respective laser beam of the plurality of laser beams into the wafer along a respective secondary cutting line of a plurality of secondary cutting lines, each of the plurality of secondary cutting lines extending in a second direction perpendicular to the first direction, and each of the plurality of secondary cutting lines being different from each other.

12. The apparatus of claim 1, wherein each of the plurality of laser heads includes:
an optical system;
a height sensor configured to measure a height from a first surface of the wafer and the laser head; and
a camera configured to image the wafer.

13. An apparatus for dicing a wafer, the apparatus comprising:
a stage configured to receive a wafer, and move the wafer in a first direction;
a plurality of laser heads, each of the plurality of laser heads including, an optical system,
a height sensor configured to generate height data based on a height from a first surface of the wafer to the laser head, and
a camera configured to generate image data based on an image of the wafer; and
as the stage moves the wafer in the first direction, the plurality of optical systems are configured to emit a plurality of laser beam into the wafer along a plurality of cutting lines, each of the plurality of cutting lines extending in the first direction and spaced apart from each other in a second direction perpendicular to the first direction.

14. The apparatus of claim 13, further comprising:
at least one controller configured to,
adjust a distance between the wafer and the plurality of laser heads based on respective height data corresponding to each of the plurality of laser heads, and
align the wafer and each of the plurality of laser heads based on the plurality of image data.

15. The apparatus of claim 13, wherein a distance in the second direction between each of a plurality of optical axes corresponding to the plurality of laser heads is equal to a distance between each of the plurality of cutting lines.

16. The apparatus of claim 13, further comprising:
a plurality of laser beam emitters configured to output the plurality of laser beams.

17. The apparatus of claim 13, further comprising:
a laser beam emitter configured to output a first laser beam; and
a beam splitter configured to split the first laser beam into the plurality of laser beams.

18. An apparatus for dicing a wafer, the apparatus comprising:
a stage configured to receive a wafer, and move the wafer in a first direction; and
a plurality of laser heads arranged in the first direction, each of the plurality of laser heads including,
an optical system,
a height sensor configured to generate height data by measuring a height from
a first surface of the wafer to the laser head, and
a camera configured to generate image data by imaging the wafer; and wherein
as the stage moves in the first direction, the optical system of each of the plurality of laser heads are each configured to emit a laser beam into the wafer along a respective cutting line of a plurality of cutting lines associated with the wafer, the plurality of cutting lines extending in the first direction and arranged in a second direction perpendicular to the first direction, and
a plurality of optical axes corresponding to the plurality of laser heads respectively encounter different cutting lines among the plurality of cutting lines.

19. The apparatus of claim 18, further comprising:
a controller configured to move at least one of the plurality of laser heads and the stage in a third direction perpendicular to the first direction and the second direction based on the height data.

20. The apparatus of claim 18, further comprising:
a controller configured to move at least one of the plurality of laser heads and the stage in at least one of the first direction and the second direction based on the image data.
